(19) United States
(12) Patent Application Publication
(10) Pub. No.: US 2026/0096173 A1
(43) Pub. Date: Apr. 2, 2026

(54) SEMICONDUCTOR DEVICES WITH FLOATING ELECTRODE STRUCTURE

(71) Applicant: Samsung Electronics Co., Ltd., Suwon-si (KR)

(72) Inventors: Dawon Jeong, Suwon-si (KR); Yonghee Park, Suwon-si (KR); Jaehyun Yoo, Suwon-si (KR); Jongwoon Yoon, Suwon-si (KR); Kyuyeop Lee, Suwon-si (KR)

(21) Appl. No.: 19/341,878

(22) Filed: Sep. 26, 2025

(30) Foreign Application Priority Data
Oct. 2, 2024 (KR) 10-2024-0134272

(51) Int. Cl. H10D 64/00; H10B 41/30; H10B 41/42; H10D 30/01; H10D 30/65; H10D 62/10; H10D 64/27

(52) U.S. Cl. CPC H10D 64/112; H10B 41/30; H10B 41/42; H10D 30/655; H10D 62/102; H10D 62/116; H10D 64/518; H10D 30/0281

(57) ABSTRACT

A semiconductor device includes a substrate, a drift region and a body region in an upper portion of the substrate, a field oxide layer on the drift region of the substrate, a gate electrode vertically overlapping a portion of the drift region and a portion of the body region, the gate electrode including a first extension portion on the field oxide layer, a source region on a first side of the gate electrode in the body region of the substrate, a drain region on a first side of the field oxide layer within the drift region of the substrate, and a floating electrode structure on the field oxide layer and including lower electrodes spaced apart from each other, an insulating layer covering top surfaces of the lower electrodes, and upper electrodes each vertically overlapping a portion of a respective one of the lower electrodes.

### CROSS-REFERENCE TO RELATED APPLICATION(S)

This application is based on and claims priority under 35 U.S.C. § 119 to Korean Patent Application No. 10-2024-0134272, filed on Oct. 2, 2024, in the Korean Intellectual Property Office, the disclosure of which is incorporated by reference herein in its entirety.

### BACKGROUND

With the development of the electronic industry and the needs of users, electronic devices have become more compact, lightweight, and multifunctional. Accordingly, there is an increasing need for a power MOS transistor, which used to be formed as a separate chip, along with various semiconductor devices. As an example of a power MOS transistor, a laterally diffused metal oxide semiconductor (LDMOS) transistor is used as a semiconductor device that may operate at a high voltage. In order to achieve a high voltage operation, a sufficient breakdown voltage of the LDMOS transistor can be desired.

### SUMMARY

The present disclosure provides a semiconductor device having excellent electrical operating characteristics.

According to an aspect of the present disclosure, a semiconductor device is provided. The semiconductor device includes a substrate, a drift region and a body region formed in an upper portion of the substrate, wherein the drift region has a first conductivity type and the body region has a second conductivity type, a field oxide layer arranged on the drift region of the substrate, a gate electrode arranged on the substrate and vertically overlapping a portion of the drift region and a portion of the body region, the gate electrode including a first extension portion arranged on the field oxide layer, a source region arranged on a first side of the gate electrode in the body region of the substrate, a drain region arranged on a first side of the field oxide layer within the drift region of the substrate, and a floating electrode structure arranged on the field oxide layer between the gate electrode and the drain region, the floating electrode structure including a plurality of lower electrodes spaced apart from each other in a first horizontal direction on a top upper surface of the field oxide layer, an insulating layer covering top surfaces of the plurality of lower electrodes, and a plurality of upper electrodes vertically overlapping a portion of each of the plurality of lower electrodes on the insulating layer.

According to another aspect of the present disclosure, a semiconductor device is provided. The semiconductor device includes a substrate, a drift region and a body region formed in an upper portion of the substrate, wherein the drift region has a first conductivity type and the body region has a second conductivity type, a field oxide layer arranged on the drift region of the substrate, a gate electrode arranged on the substrate and arranged to vertically overlap a portion of the drift region and a portion of the body region, a source region arranged on a first side of the gate electrode in the body region of the substrate, a drain region arranged on a first side of the field oxide layer within the drift region of the substrate, and a floating electrode structure arranged on the field oxide layer between the gate electrode and the drain region, the floating electrode structure including a plurality of lower electrodes spaced apart from each other by a first separation distance in a first horizontal direction on a top upper surface of the field oxide layer, a plurality of upper electrodes offset from each of the plurality of lower electrodes in the first horizontal direction and spaced apart from each other by a second separation distance equal to the first separation distance in the first horizontal direction, and an insulating layer arranged between the plurality of lower electrodes and the plurality of upper electrodes.

According to another aspect of the present disclosure, a semiconductor device is provided. The semiconductor device includes a flash memory cell arranged on a first region of a substrate and a metal oxide semiconductor (MOS) transistor arranged on a second region of the substrate, wherein the MOS transistor includes a drift region and a body region formed in an upper portion of the substrate, and the drift region has a first conductivity type and the body region has a second conductivity type, a field oxide layer arranged on the drift region of the substrate, a gate electrode arranged on the substrate and arranged to vertically overlap a portion of the drift region and a portion of the body region, a source region arranged on a first side of the gate electrode in the body region of the substrate, a drain region arranged on a first side of the field oxide layer within the drift region of the substrate, and a floating electrode structure arranged on the field oxide layer and between the gate electrode and the drain region, the floating electrode structure including a plurality of lower electrodes arranged to be spaced apart on a top surface of the field oxide layer, an insulating layer covering top surfaces of the plurality of lower electrodes, and a plurality of upper electrodes vertically overlapping a portion of each of the plurality of lower electrodes on the insulating layer.

### BRIEF DESCRIPTION OF THE DRAWINGS

Implementations will be more clearly understood from the following detailed description taken in conjunction with the accompanying drawings in which:

FIG. 1 is a perspective view schematically illustrating a semiconductor device according to implementations;

FIG. 2 is a cross-sectional view illustrating a portion of a first region of FIG. 1;

FIG. 3 is a cross-sectional view illustrating a portion of a second region of FIG. 1;

FIG. 4 is an enlarged view of a portion EN of FIG. 3;

FIG. 5 is a schematic layout view of a floating electrode structure of FIG. 3;

FIG. 6 is a schematic diagram illustrating a method of driving a semiconductor device according to implementations;

FIG. 7 is a cross-sectional view illustrating a semiconductor device according to implementations;

FIG. 8 is an enlarged view of a portion EN of FIG. 7;

FIG. 9 is a cross-sectional view illustrating a semiconductor device according to implementations;

FIG. 10 is an enlarged view of a portion EN of FIG. 9;

FIG. 11 is a cross-sectional view illustrating a semiconductor device according to implementations;

FIG. 12 is an enlarged view of a portion EN of FIG. 11;

FIG. 13 is a cross-sectional view illustrating a semiconductor device according to implementations;

FIGS. 14A, 14B, 15A, 15B, 16A, 16B, 17A, 17B, 18A, 18B, 19A, 19B, 20A, 20B, 21A, 21B, 22A, 22B, 23A, and 23B are cross-sectional views illustrating a method of manufacturing a semiconductor device according to implementations.

### DETAILED DESCRIPTION

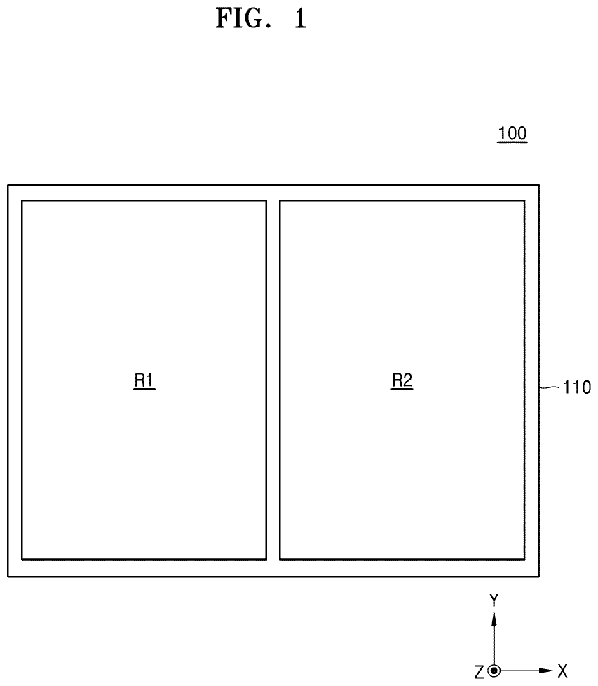

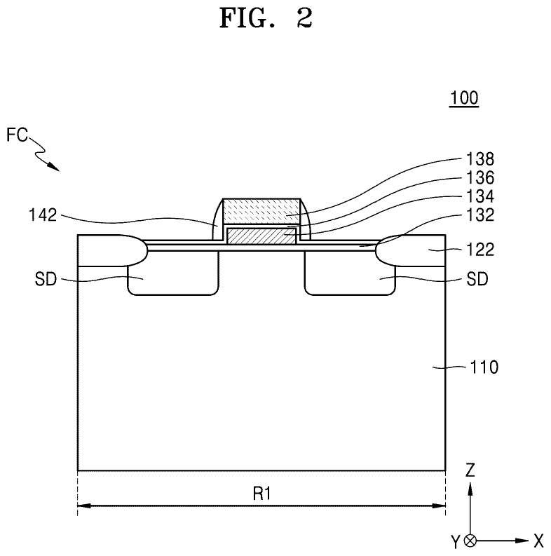

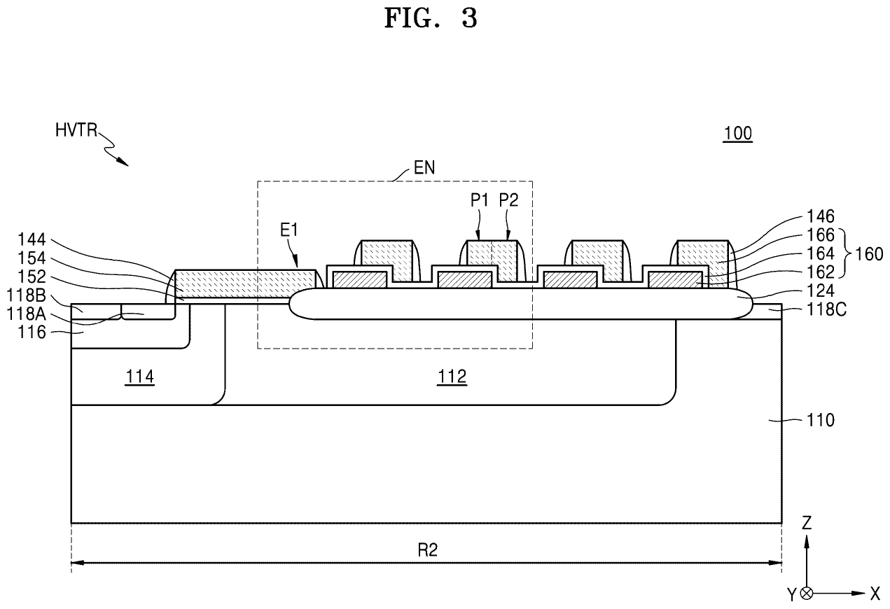

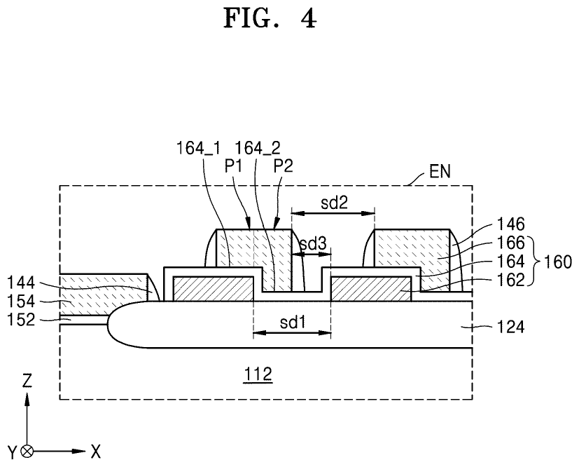

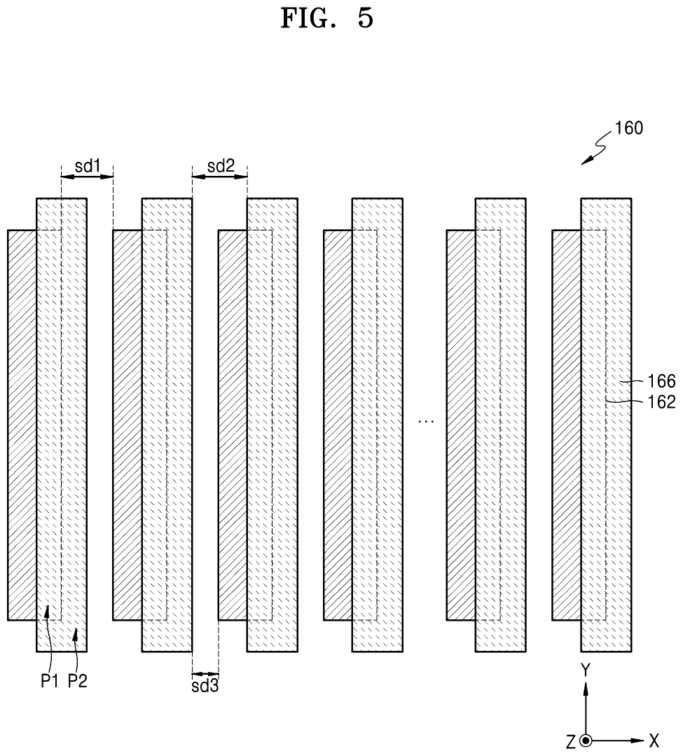

FIG. 1 is a perspective view schematically illustrating a semiconductor device 100 according to implementations. FIG. 2 is a cross-sectional view illustrating a portion of a first region R1 of FIG. 1, and FIG. 3 is a cross-sectional view illustrating a portion of a second region R2 of FIG. 1. FIG. 4 is an enlarged view of a portion EN of FIG. 3. FIG. 5 is a schematic layout view of a floating electrode structure 160 of FIG. 3.

Referring to FIGS. 1 to 5, a semiconductor device 100 may include a flash memory cell FC that is formed in a first region R1 of a substrate 110 and a metal oxide transistor (MOS) transistor HVTR that is formed in a second region R2 of the substrate 110.

The flash memory cell FC may be arranged on the first region R1 of the substrate 110 and may constitute an embedded flash memory device.

The substrate 110 may include a semiconductor substrate such as a silicon substrate, a germanium substrate, or a silicon-germanium substrate. In some implementations, a silicon-on-insulator (SOI) substrate or a germanium-on-insulator (GOI) substrate may be used as the substrate 110.

A device isolation layer 122 may be formed on the substrate 110. In implementations, the device isolation layer 122 may be formed by oxidizing a portion of the substrate 110 in a local oxidation of silicon (LOCOS) manner. In other implementations, the device isolation layer 122 may be formed by removing a portion of the substrate 110 to form a device isolation trench and then filling silicon oxide in the device isolation trench.

The flash memory cell FC may include a tunneling insulating layer 132, a floating gate electrode 134, a blocking insulating layer 136, and a control gate electrode 138 sequentially arranged on the substrate 110.

In implementations, the tunneling insulation layer 132 may be arranged on a top surface of the substrate 110. In implementations, the tunneling insulating layer 132 may include silicon oxide.

In implementations, the floating gate electrode 134 may be arranged on the tunneling insulation layer 132. In implementations, the floating gate electrode 134 may include doped polysilicon.

In implementations, the blocking insulating layer 136 may be arranged on a top upper surface of the floating gate electrode 134. In implementations, the blocking insulating layer 136 may include silicon oxide or a high-k dielectric material. In some implementations, the blocking insulating layer 136 may be conformally formed on the top surface of the floating gate electrode 134 and on the top surface of the substrate 110.

In some other implementations, the blocking insulating layer 136 may be formed by oxidizing a portion of the floating gate electrode 134 in a local oxidation of silicon (LOCOS) manner. In this case, the blocking insulating layer 136 may be arranged on the upper surface of the floating gate electrode 134, and optionally, an insulating liner may be further conformally arranged on the blocking insulating layer 136, the sidewall of the floating gate electrode 134, and the top surface of the substrate 110.

In implementations, the control gate electrode 138 may be arranged on the blocking insulation layer 136. In some implementations, the control gate electrode 138 may include doped polysilicon.

In implementations, a first spacer 142 may be further arranged on a sidewall of the floating gate electrode 134 and a sidewall of the control gate electrode 138. The first spacer 142 may include silicon nitride or silicon oxynitride.

The flash memory cell FC may further include a pair of impurity regions SD arranged on both sides of the floating gate electrode 134 (or on both sides of the control gate electrode 138) at an upper portion of the substrate 110. The pair of impurity regions SD may be a source region and a drain region of the flash memory cell FC.

In implementations, the flash memory cell FC may be configured to store data in a manner in which electrons are tunneled from a channel region defined on the substrate 110 by a voltage applied to the control gate electrode 138 and electrons are stored in the floating gate electrode 134. FIG. 2 illustrates that the flash memory cell FC includes only one floating gate electrode 134 and one control gate electrode 138 arranged between the pair of impurity regions SD. However, in some implementations, a plurality of flash memory cells FC may constitute a memory string, and in this case, a plurality of gate stacks each composed of one floating gate electrode 134 and one control gate electrode 138 may be spaced apart between a pair of impurity regions SD.

The MOS transistor HVTR may be arranged on the second region R2 of the substrate 110. The MOS transistor HVTR may include a gate electrode 154 and a floating electrode structure 160, which are arranged on the second region R2 of the substrate 110.

A drift region 112 having a first conductivity type and a well region 114 having a second conductivity type may be arranged on the second region R2 of the substrate 110. The drift region 112 and the well region 114 may be arranged side by side in the lateral direction. A body region 116 having a second conductivity type may be arranged in the well region 114.

In some implementations, the first conductivity type may be an n-type and the second conductivity type may be a p-type. In this case, the MOS transistor HVTR may be referred to as an n-type lateral double diffused metal oxide semiconductor (LDMOS) transistor. In other implementations, the first conductivity type may be a p-type and the second conductivity type may be an n-type. In this case, the MOS transistor HVTR may be referred to as a p-type LDMOS transistor.

A field oxide layer 124 may be arranged on the drift region 112. The field oxide layer 124 may be formed by oxidizing a portion of the substrate 110 in a LOCOS manner. The field oxide layer 124 may be formed by oxidizing a portion of the substrate 110, and a top surface of the field oxide layer 124 may be arranged at a vertical level higher than a top surface of the substrate 110 adjacent to the field oxide layer 124.

A source region 118A and a body contact region 118B may be arranged in a portion of the body region 116 adjacent to the top surface of the substrate 110. The source region 118A may be a region doped with the first conductivity type impurities at a relatively high concentration, and the body contact region 118B may be a region doped with the second conductivity type impurities at a relatively high concentration. The source region 118A and the body contact region 118B may be arranged adjacent to each other.

A drain region 118C may be arranged in a portion of the drift region 112 adjacent to the top surface of the substrate 110. In some implementations, the drain region 118C may be arranged on one side of the field oxide layer 124. In some implementations, the drain region 118C may be a region doped with the first conductivity type impurities at a relatively high concentration.

A gate insulating layer 152 may be arranged on the top surface of the substrate 110. The gate insulating layer 152 may be arranged to overlap a portion of the body region 116 and a portion of the drift region 112. The gate insulating layer 152 may be in contact with the sidewall of the field oxide layer 124. In some implementations, the gate insulating layer 152 may include silicon oxide.

A gate electrode 154 may be arranged on the gate insulation layer 152. The gate electrode 154 may be arranged to overlap a portion of the body region 116 and a portion of the drift region 112. In some implementations, the gate electrode 154 may include polysilicon.

In some implementations, the gate electrode 154 may include a first extension portion E1. The first extension portion E1 may indicate a portion of the gate electrode 154 arranged on the top surface of the field oxide layer 124. That is, the first extension portion E1 may indicate a portion of the gate electrode 154 vertically overlapping the field oxide layer 124.

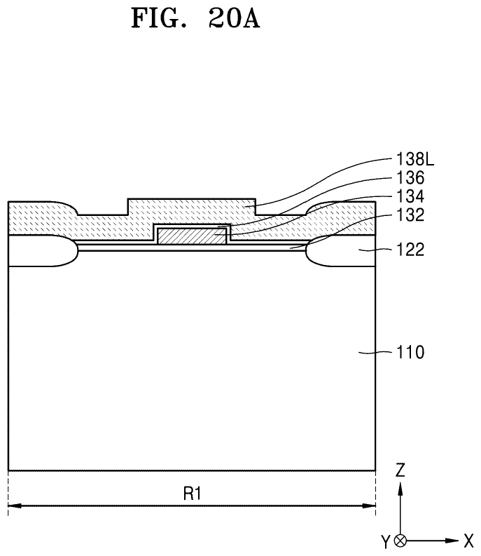

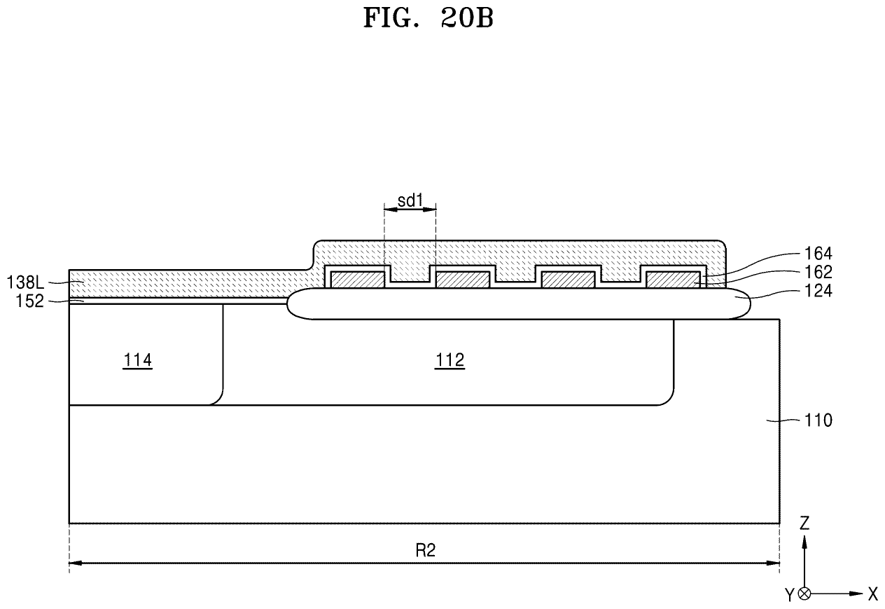

In some implementations, the gate electrode 154 may be formed simultaneously in a process of forming the control gate electrode 138 of the flash memory cell FC. For example, a second gate electrode layer 138L (see FIGS. 20A and 20B) may be formed on the first region R1 and the second region R2 of the substrate 110, and then the second gate electrode layer 138L may be patterned using a mask pattern to form a control gate electrode 138 on the first region R1 and to form a gate electrode 154 on the second region R2.

A second spacer 144 may be arranged on either sidewall of the gate electrode 154. The second spacer 144 may include silicon nitride or silicon oxynitride.

The floating electrode structure 160 may be arranged on the field oxide layer 124. In some implementations, the floating electrode structure 160 may be spaced apart from the gate electrode 154 in a first horizontal direction X. For example, the floating electrode structure 160 may be arranged to be spaced apart from the first extension portion E1 of the gate electrode 154 in the first horizontal direction X.

The floating electrode structure 160 may include a plurality of lower electrodes 162, an insulating layer 164, and a plurality of upper electrodes 166.

In some implementations, the plurality of lower electrodes 162 may be spaced apart from each other in the first horizontal direction X. For example, the plurality of lower electrodes 162 may be spaced apart from each other to have a constant first separation distance sd1. For example, two adjacent lower electrodes 162 among the plurality of lower electrodes 162 may be arranged to be spaced apart from each other by the first separation distance sd1.

In some implementations, the bottom surfaces of the plurality of lower electrodes 162 may be arranged on the top surface of the field oxide layer 124 and may be in contact with the top surface of the field oxide layer 124. The top surfaces of the plurality of lower electrodes 162 may be arranged at same vertical level. In some implementations, each of the plurality of lower electrodes 162 may have a rectangular vertical cross-section.

In some implementations, the plurality of lower electrodes 162 may include polysilicon.

In some implementations, the insulating layer 164 may be arranged on the top surfaces and the sidewalls of the plurality of lower electrodes 162. In some implementations, as illustrated in FIG. 3, the insulating layer 164 may extend onto the top surface of the field oxide layer 124.

In configurations, the insulating layer 164 may include silicon oxide or a high-k dielectric material.

The plurality of upper electrodes 166 may be arranged on the insulating layer 164, and may be arranged to be offset from the plurality of lower electrodes 162 in the first horizontal direction X. Here, the expression that it is offset and arranged in the first horizontal direction X may mean that it is arranged to be spaced apart by a predetermined distance. For example, the plurality of upper electrodes 166 may be arranged on the plurality of lower electrodes 162, respectively, and the sidewall of each of the plurality of upper electrodes 166 may be arranged at a position spaced apart from the sidewall of the corresponding lower electrode 162 in the first horizontal direction X. Each of the plurality of upper electrodes 166 may vertically overlap a portion of each of the plurality of lower electrodes 162.

In some implementations, the plurality of upper electrodes 166 may be spaced apart from each other in the first horizontal direction X. For example, the plurality of upper electrodes 166 may be spaced apart from each other to have a constant second separation distance sd2, and the second separation distance sd2 may be substantially equal to the first separation distance sd1. For example, two adjacent upper electrodes 166 among the plurality of upper electrodes 166 may be spaced apart from each other by the second separation distance sd2 substantially the same as the first separation distance sd1.

Here, the expression that the second separation distance sd2 is substantially the same as the first separation distance sd1 may mean having a difference of 5% or less or 10% or less with respect to each other in consideration of a process error or tolerance that may occur in a process for forming the plurality of lower electrodes 162 and the plurality of upper electrodes 166.

In some implementations, each of the plurality of upper electrodes 166 may have an inverted L-shaped vertical cross-section. For example, as illustrated in FIG. 3, each of the plurality of upper electrodes 166 may have a flat top surface and a bottom surface having a step (or level difference). In addition, each of the plurality of upper electrodes 166 may have a top surface arranged at same vertical level. In some implementations, the plurality of upper electrodes 166 may include polysilicon.

In some implementations, each of the plurality of upper electrodes 166 may include a first portion P1 and a second portion P2. The first portion P1 may refer to a portion of the upper electrode 166 arranged on the top surface of the corresponding lower electrode 162. A first portion 164_1 of the insulating layer 164 may be arranged between the bottom surface of the first portion P1 and the lower electrode 162. The second portion P2 may refer to a portion of the upper electrode 166 arranged on a sidewall of the corresponding lower electrode 162. The second portion P2 may be integrally connected to the first portion P1. A second portion 164_2 of the insulating layer 164 may be arranged between the sidewall of the second portion P2 and the lower electrode 162, and between the bottom surface of the second portion P2 and the top surface of the field oxide layer 124.

In some implementations, the top surface of the second portion P2 may be arranged at the same vertical level as the top surface of the first portion P1, and the bottom surface of the second portion P2 may be arranged at a lower vertical level than the bottom surface of the first portion P1.

In some implementations, the sidewall of the second portion P2 may be spaced apart from the lower electrode 162 adjacent thereto at a third separation distance sd3 in the first horizontal direction X, and the third separation distance sd3 may be less than the first separation distance sd1 or the second separation distance sd2. In some implementations, the third separation distance sd3 may be in a range of 20% to 80%, 30% to 70%, or 40% to 60% of the first separation distance sd1 or the second separation distance sd2.

In some implementations, as the plurality of upper electrodes 166 are arranged to be offset from the plurality of lower electrodes 162, respectively, one lower electrode 162 and the corresponding upper electrode 166 (e.g., a first electrode stack including a first lower electrode and a first upper electrode on the first lower electrode) may be arranged to be spaced apart by a third separation distance sd3 from another lower electrode 162 adjacent thereto and another upper electrode 166 corresponding to the other lower electrode 162 (e.g., a second electrode stack including a second lower electrode and a second upper electrode on the second lower electrode). For example, a sidewall of the second portion P2 of another upper electrode (e.g., a second upper electrode) may be arranged to be spaced apart by a third separation distance sd3 from a sidewall of the lower electrode (e.g., the first lower electrode). Therefore, even when the minimum separation distance allowed by a design rule is the first separation distance sd1 or the second separation distance sd2, the first electrode stack and the second electrode stack may be spaced apart from each other by a third separation distance sd3 less than the first separation distance sd1 or the second separation distance sd2.

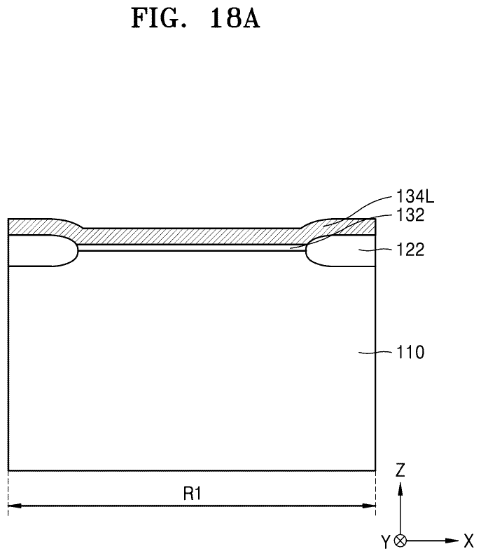

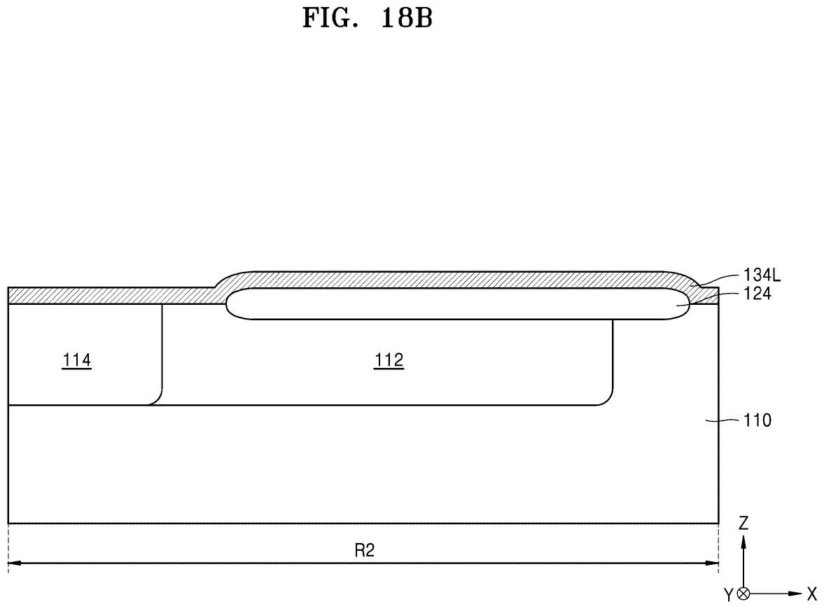

In some implementations, the plurality of lower electrodes 162 may be simultaneously formed in a process of forming the floating gate electrode 134 of the flash memory cell FC. For example, a first gate electrode layer 134L (see FIGS. 18A and 18B) may be formed on the first region R1 and the second region R2 of the substrate 110, and then the first gate electrode layer 134L may be patterned using a mask pattern to form a floating gate electrode 134 on the first region R1 and to form a plurality of lower electrodes 162 on the second region R2.

In some implementations, the plurality of upper electrodes 166 may be simultaneously formed in a process of forming the control gate electrode 138 of the flash memory cell FC. For example, a second gate electrode layer 138L (see FIGS. 20A and 20B) may be formed on the first region R1 and the second region R2 of the substrate 110, and then the second gate electrode layer 138L may be patterned using a mask pattern to form a control gate electrode 138 on the first region R1 and to form a gate electrode 154 and a plurality of upper electrodes 166 on the second region R2.

According to implementations, gaps between a plurality of electrodes may be minimized without being limited to a minimum design rule, and an electric field concentrated on the edge of the gate electrode 154 may be effectively distributed by a coupling effect between the upper electrode 166 and the lower electrode 162, and thus the semiconductor device 100 may have a high breakdown voltage. In addition, the floating electrode structure 160 may be simultaneously formed in a process of manufacturing the floating gate electrode 134 and the control gate electrode 138 of the embedded flash device. Accordingly, the number of process steps for manufacturing the semiconductor device 100 may be reduced.

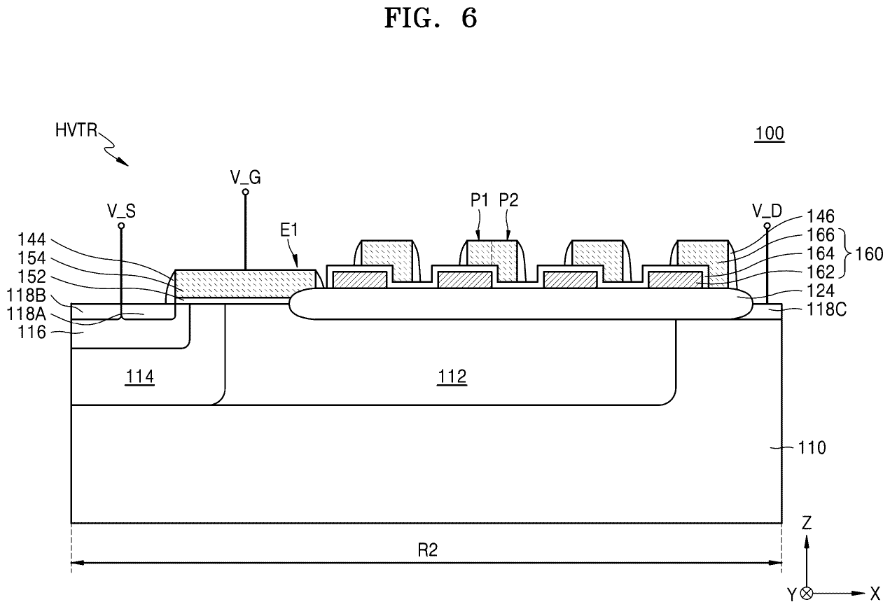

FIG. 6 is a schematic diagram illustrating a method of driving a semiconductor device 100 according to implementations.

Referring to FIG. 6, when a MOS transistor HVTR is turned on, a source voltage V_S may be applied to the source region 118A and the body contact region 118B, a drain voltage V_D may be applied to the drain region 118C, and a gate voltage V_G may be applied to the gate electrode 154. In this case, the floating electrode structure 160 may be configured to be floated without receiving a separate voltage.

According to implementations, as the floating electrode structure 160 is formed in a two-layer structure including a plurality of lower electrodes 162 and a plurality of upper electrodes 166, the gaps between the plurality of electrodes may be minimized without being limited to a minimum design rule. In addition, the electric field concentration phenomenon between the gate electrode 154 and the drain region 118C may be mitigated or reduced by an additional coupling effect between the plurality of lower electrodes 162 and the plurality of upper electrodes 166. Therefore, the semiconductor device 100 may have an excellent or relatively high breakdown voltage.

For example, a simulation test was performed using the semiconductor device 100 described with reference to FIG. 6. As a comparative example, a semiconductor device having a floating electrode structure including only a plurality of lower electrodes 162 was used.

The semiconductor device according to an implementation showed an increased breakdown voltage compared to the comparative example, which is approximately 107% of the breakdown voltage of the semiconductor device according to the comparative example. In addition, the semiconductor device according to the implementation exhibited an on-resistance value that is reduced by about 13% from an on-resistance value of the semiconductor device according to the comparative example. Therefore, it is possible to implement an LDMOS device with an improved operating speed by securing a predetermined breakdown voltage while simultaneously reducing resistance.

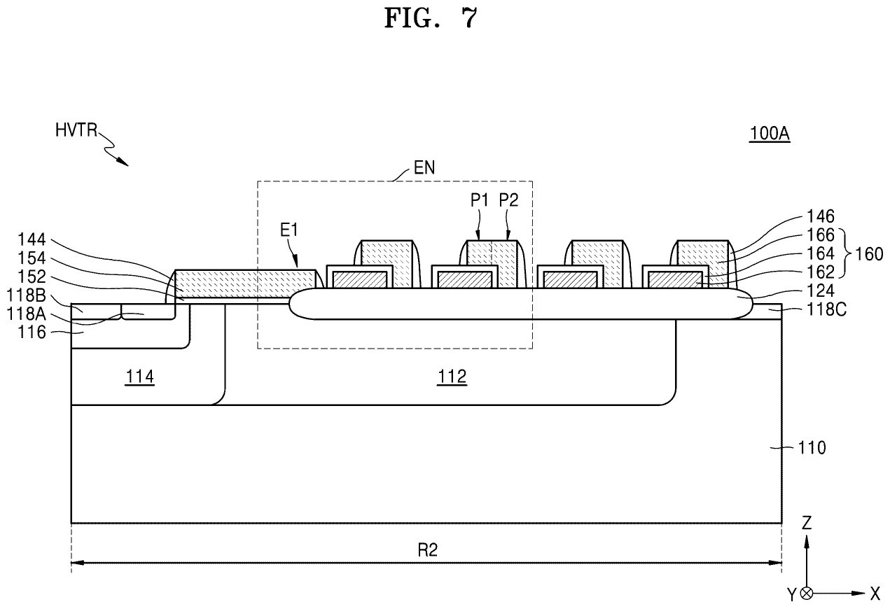

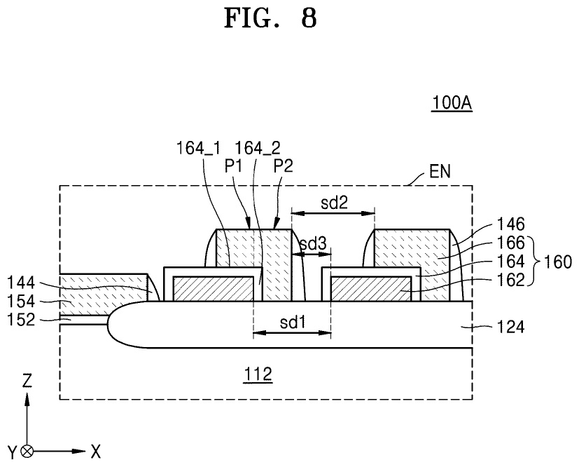

FIG. 7 is a cross-sectional view illustrating a semiconductor device 100A according to implementations, and FIG. 8 is an enlarged view of a portion EN of FIG. 7.

Referring to FIGS. 7 and 8, an insulating layer 164 of the floating electrode structure 160 may be arranged only on a top surface and a sidewall of the lower electrode 162. The insulating layer 164 may include a first portion 164_1 and a second portion 164_2, and the first portion 164_1 of the insulating layer 164 may be arranged between the bottom surface of the first portion P1 of the upper electrode 166 and the top surface of the lower electrode 162. The second portion 164_2 of the insulating layer 164 may be arranged between the sidewall of the second portion P2 of the upper electrode 166 and the sidewall of the lower electrode 162.

The insulating layer 164 may not be arranged between the top surface of the field oxide layer 124 and the bottom surface of the second portion P2 of the upper electrode 166, and the bottom surface of the second portion P2 of the upper electrode 166 may be in contact with the top surface of the field oxide layer 124.

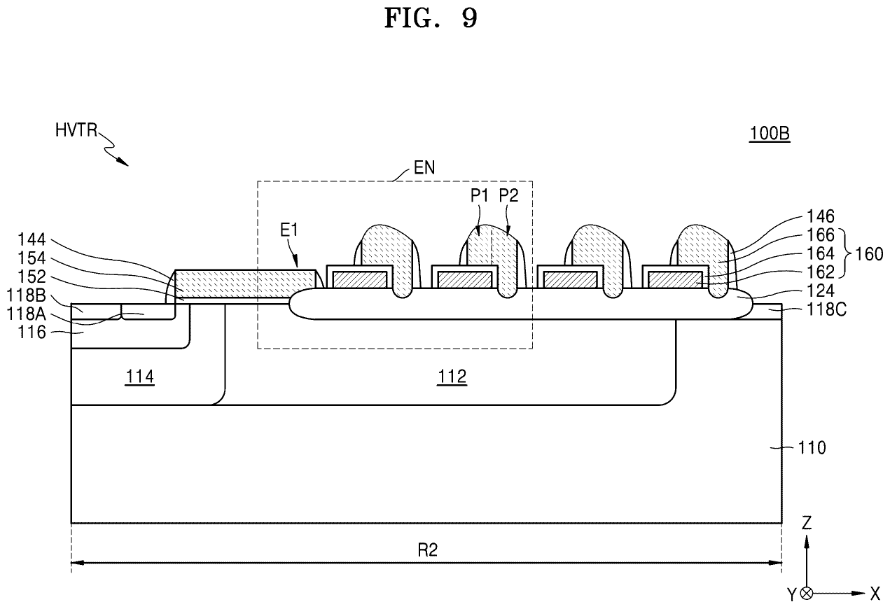

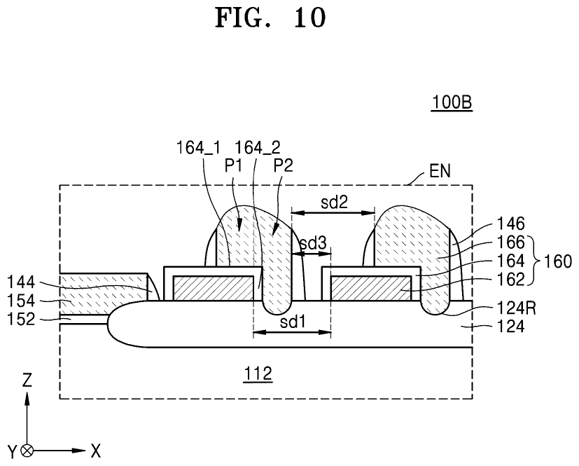

FIG. 9 is a cross-sectional view illustrating a semiconductor device 100B according to implementations, and FIG. 10 is an enlarged view of a portion EN of FIG. 9.

Referring to FIGS. 9 and 10, the second portion P2 of each of the plurality of upper electrodes 166 may extend into a recess 124R formed above the field oxide layer 124, and the bottom surface of the second portion P2 may be arranged at a vertical level lower than the bottom surfaces of the plurality of lower electrodes 162.

In some implementations, recesses 124R may be formed above the field oxide layer 124 by removing some portions of an upper portion of the field oxide layer 124 in a process of forming the plurality of lower electrodes 162 and the insulating layer 164, or in a process of forming the flash memory cell FC (see FIG. 2) on the first region R1. In this case, a portion of the plurality of upper electrodes 166, that is, a bottom of the second portion P2, may be formed to fill the inside of the recess 124R.

In some implementations, the top surface of the first portion P1 of the plurality of upper electrodes 166 may have a top surface of a curved surface such that the top surface of the first portion P1 is arranged at a higher vertical level than the top surface of the second portion P2.

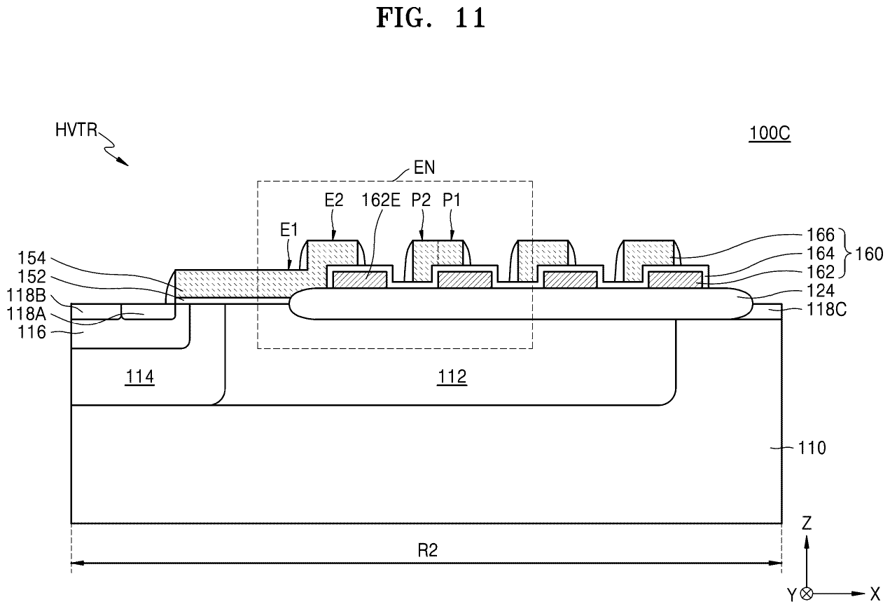

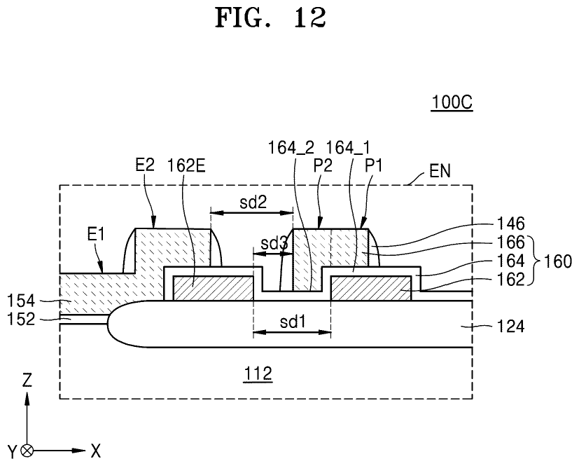

FIG. 11 is a cross-sectional view illustrating a semiconductor device 100C according to implementations, and FIG. 12 is an enlarged view of a portion EN of FIG. 11.

Referring to FIGS. 11 and 12, the floating electrode structure 160 may further include an edge electrode 162E arranged between the plurality of lower electrodes 162 and the gate electrode 154. The edge electrode 162E may be spaced apart from the plurality of lower electrodes 162 by a first separation distance sd1. The top surface and the sidewall of the edge electrode 162E may be covered by an insulating layer 164, and the edge electrode 162E may be connected to and adjacent to the first extension portion E1 of the gate electrode 154 with the insulating layer 164 therebetween.

The gate electrode 154 may further include a second extension portion E2. The second extension portion E2 may indicate a portion of the gate electrode 154 arranged on the top surface of the floating electrode structure 160, for example, the top surface of the edge electrode 162E. The second extension portion E2 may be arranged on the top surface of the edge electrode 162E, and may be arranged at a higher vertical level than the first extension portion E1.

In some implementations, the top surface of the second extension portion E2 may be arranged at the same vertical level as the top surfaces of the plurality of upper electrodes 166.

When the semiconductor device 100C is turned on, a gate voltage V_G (see FIG. 6) may be applied to the gate electrode 154 and the edge electrode 162E may be floated.

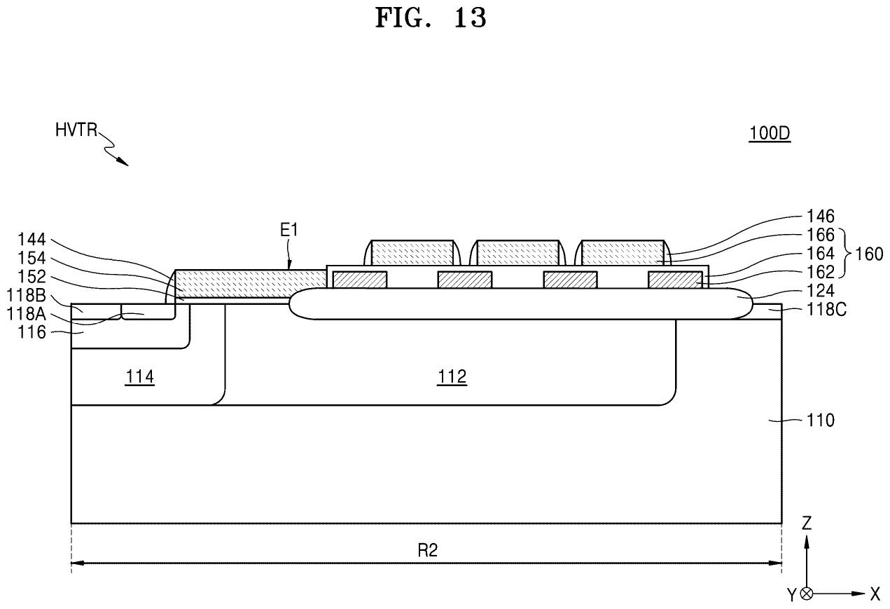

FIG. 13 is a cross-sectional view illustrating a semiconductor device 100D according to implementations.

Referring to FIG. 13, a floating electrode structure 160 may include a plurality of lower electrodes 162, an insulating layer 164 arranged on top surfaces and sidewalls of the plurality of lower electrodes 162 and filling a space between the plurality of lower electrodes 162, and a plurality of upper electrodes 166 arranged on the insulating layer 164.

In some implementations, the insulating layer 164 may have a flat top level while filling a space between the plurality of lower electrodes 162. In example implementations, the plurality of upper electrodes 166 may be arranged to be spaced apart from the plurality of lower electrodes 162 in the first horizontal direction X. Each of the plurality of upper electrodes 166 may vertically overlap at least a portion of the plurality of lower electrodes 162.

In some implementations, as illustrated in FIG. 13, one upper electrode 166 may be arranged to vertically overlap portions of the two adjacent lower electrodes 162, and one lower electrode 162 may be arranged to vertically overlap portions of the two adjacent upper electrodes 166.

In some implementations, each of the plurality of lower electrodes 162 may have a rectangular vertical cross-section, and each of the plurality of upper electrodes 166 may have a rectangular vertical cross-section.

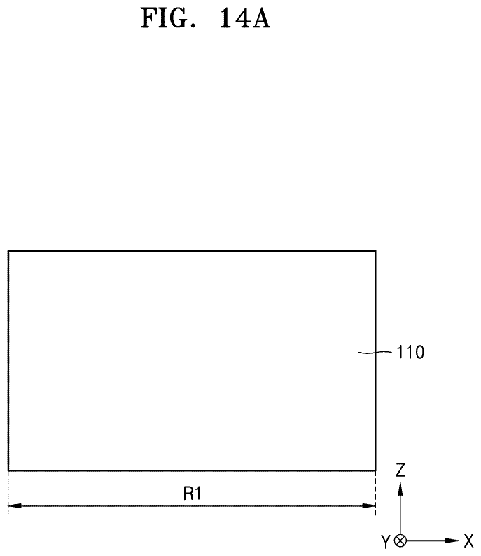

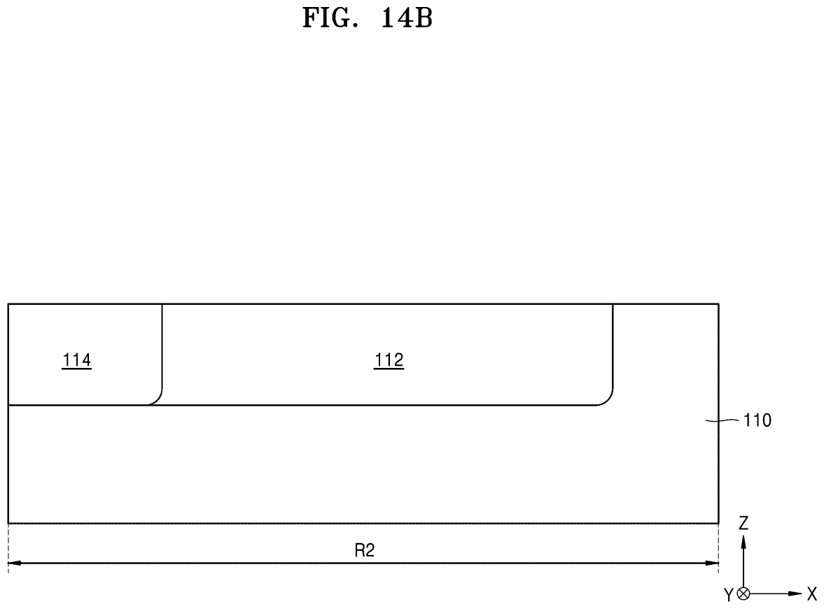

FIGS. 14A, 14B, 15A, 15B, 16A, 16B, 17A, 17B, 18A, 18B, 19A, 19B, 20A, 20B, 21A, 21B, 22A, 22B, 23A, and 23B are cross-sectional views illustrating a method of manufacturing a semiconductor device 100 according to implementations.

Referring to FIGS. 14A and 14B, a drift region 112 and a well region 114 may be formed by implanting impurity ions into a second region R2 of a substrate 110. In some implementations, the drift region 112 may be formed by injecting first conductivity type (e.g., n-type) impurities, and the well region 114 may be formed by injecting second conductivity type (e.g., p-type) impurities.

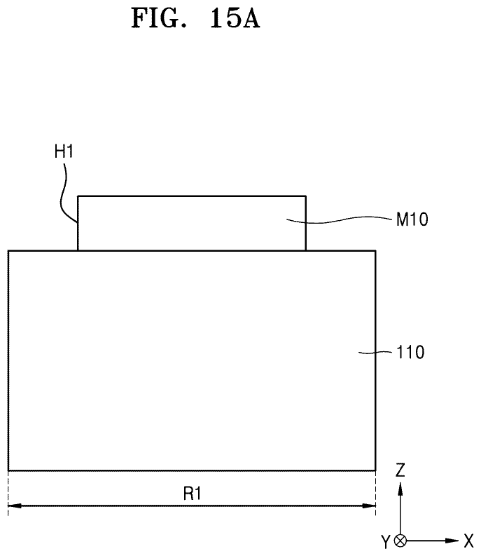

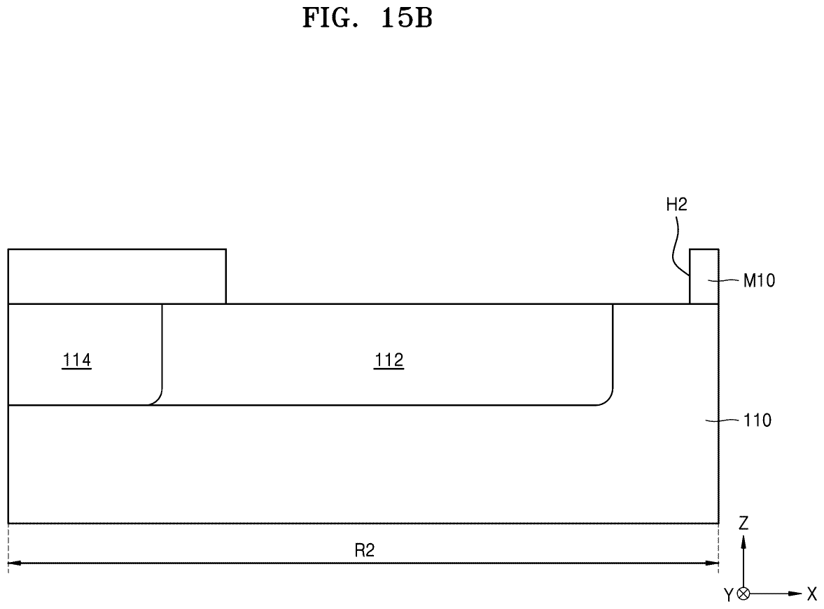

Referring to FIGS. 15A and 15B, hardmask patterns M10 may be formed on the first region R1 and the second region R2 of the substrate 110, respectively. In some implementations, the hardmask patterns M10 may include silicon nitride. The hardmask pattern M10 may include a first opening H exposing a portion of the top surface of the substrate 110 on the first region R1 and a second opening H2 exposing a portion of the top surface of the substrate 110 on the second region R2.

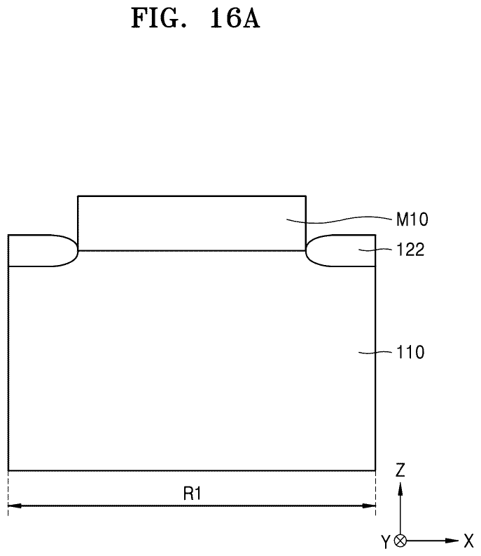

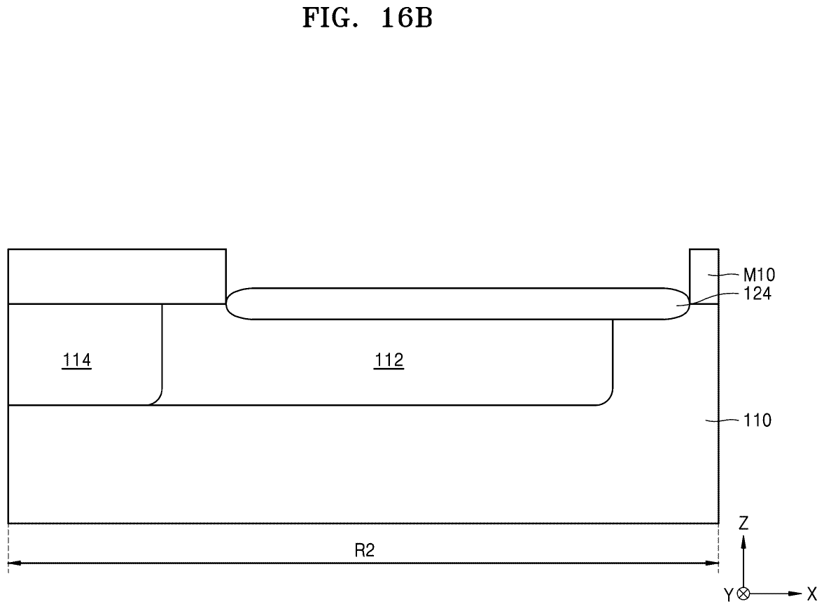

Referring to FIGS. 16A and 16B, an oxidation process may be performed on portions of the top surface of the substrate 110 exposed by the first opening H1 and the second opening H2 to form a device isolation layer 122 and a field oxide layer 124 in the first opening H1 and the second opening H2, respectively.

In some implementations, the oxidation process for forming the device isolation layer 122 and the field oxide layer 124 may be a thermal oxidation process or a plasma assisted oxidation process.

In some implementations, a portion of the substrate 110 is consumed in the process of forming the device isolation layer 122 and the field oxide layer 124, so that the bottom surface of each of the device isolation layer 122 and the field oxide layer 124 may protrude toward the substrate 110. For example, a portion of the top surface of the substrate 110 in contact with the device isolation layer 122 may be arranged at a lower vertical level than a portion of the top surface of the substrate 110 covered by the hardmask pattern M10.

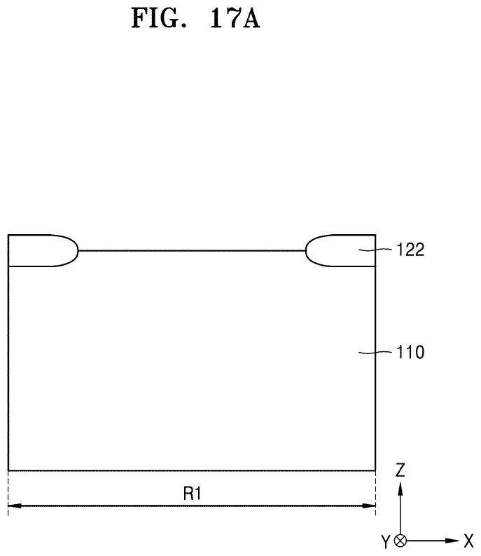

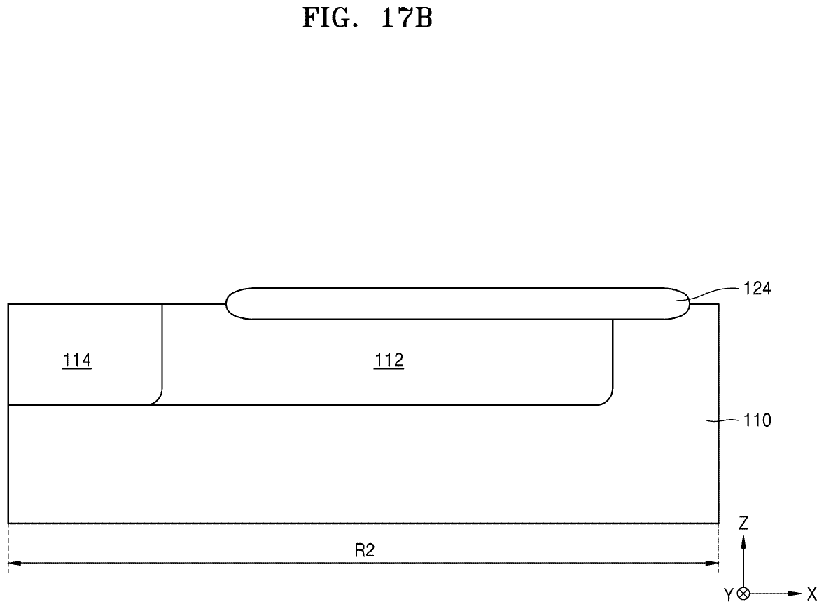

Referring to FIGS. 17A and 17B, the hardmask patterns M10 may be removed from the first and second regions R1 and R2.

Referring to FIGS. 18A and 18B, a tunneling insulation layer 132 may be formed on the first region R1 of the substrate 110. For example, the tunneling insulating layer 132 may be formed using silicon oxide. In some implementations, the tunneling insulation layer 132 may be formed by performing an oxidation process on the top surface of the substrate 110, or may be formed by a chemical vapor deposition (CVD) process or an atomic layer deposition (ALD) process.

Thereafter, a first gate electrode layer 134L may be formed on the first region R1 and the second region R2 of the substrate 110. In some implementations, the first gate electrode layer 134L may be formed by a CVD process or an ALD process using polysilicon.

The first gate electrode layer 134L may be arranged on the tunneling insulating layer 132 and the device isolation layer 122 on the first region R1, and the first gate electrode layer 134L may be arranged on the top surface of the substrate 110 and the field oxide layer 124 on the second region R2.

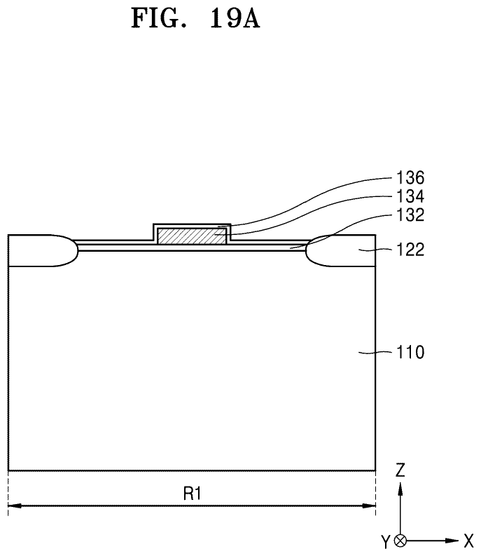

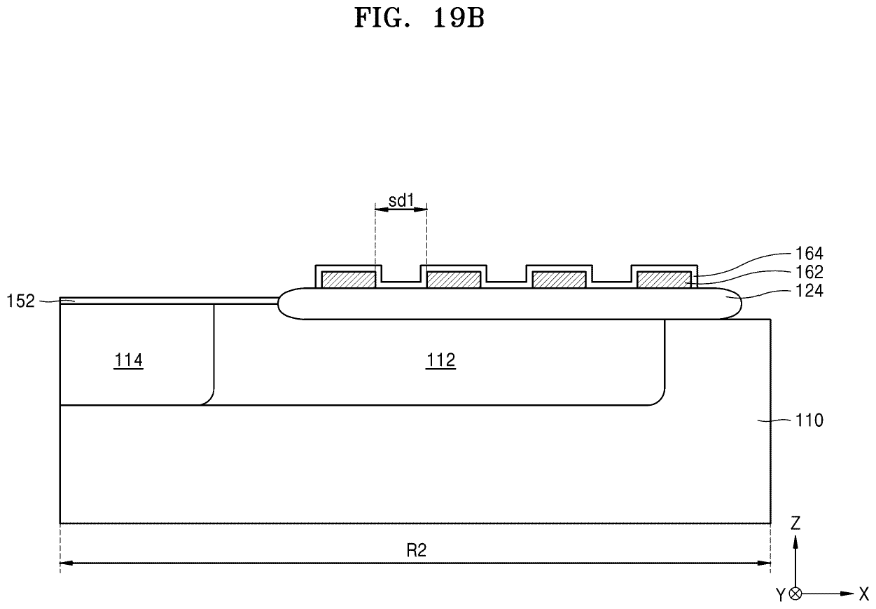

Referring to FIGS. 19A and 19B, a mask pattern may be formed on the first gate electrode layer 134L, and the first gate electrode layer 134L may be patterned using the mask pattern to form a floating gate electrode 134 on the first region R1, and a plurality of lower electrodes 162 may be formed on the second region R2.

In some implementations, the plurality of lower electrodes 162 may be arranged to be spaced apart by the first separation distance sd1.

Thereafter, a blocking insulating layer 136 may be formed on the floating gate electrode 134 on the first region R1, an insulating layer 164 may be formed on the plurality of lower electrodes 162 on the second region R2, and a gate insulating layer 152 may be formed on the top surface of the substrate 110 on the second region R2.

In some implementations, the blocking insulating layer 136 may include silicon oxide or a high-k dielectric material. In some implementations, the insulating layer 164 may include silicon oxide or a high-k dielectric material. In some implementations, the gate insulating layer 152 may include silicon oxide.

In some implementations, the insulating layer 164 may be formed simultaneously in a process for forming the blocking insulating layer 136. In other implementations, the process for forming the insulating layer 164 may be performed before or after the process for forming the blocking insulating layer 136.

In some implementations, the gate insulating layer 152 may be formed simultaneously in a process for forming the blocking insulating layer 136. In other implementations, the process for forming the gate insulating layer 152 may be performed before or after the process for forming the blocking insulating layer 136.

Referring to FIGS. 20A and 20B, a second gate electrode layer 138L may be formed on the blocking insulating layer 136 on the first region R1, and the second gate electrode layer 138L may be formed on the gate insulating layer 152 and the insulating layer 164 on the second region R2.

In some implementations, the second gate electrode layer 138L may be formed by a CVD process or an ALD process using polysilicon.

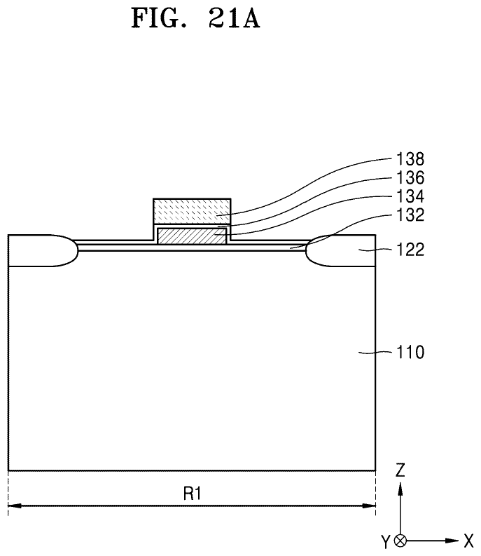

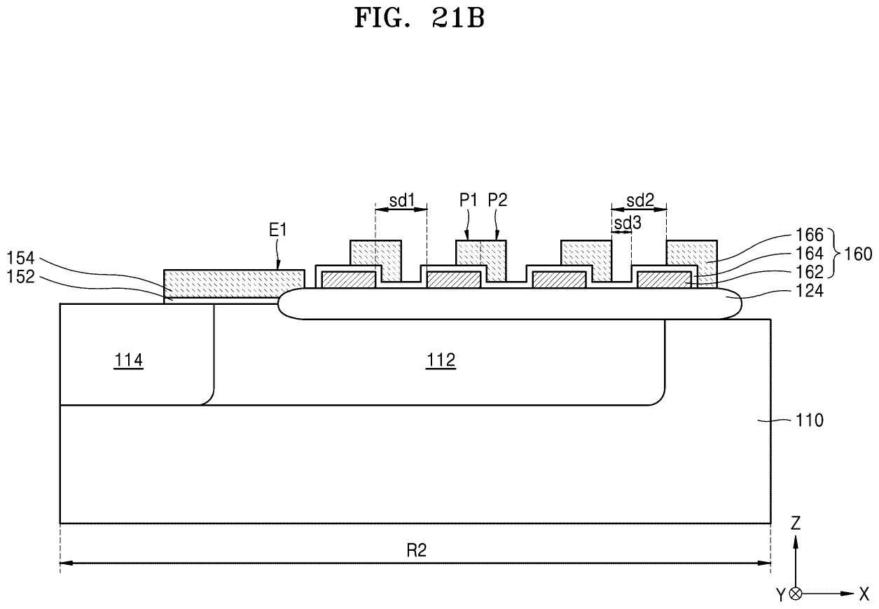

Referring to FIGS. 21A and 21B, a mask pattern may be formed on the second gate electrode layer 138L, a control gate electrode 138 may be formed on the first region R1 and a gate electrode 154 and a plurality of upper electrodes 166 may be formed on the second region R2, by patterning the second gate electrode layer 138L using the mask pattern as an etching mask.

In some implementations, the control gate electrode 138 may be formed on the blocking insulation layer 136 on the first region R1, and the gate electrode 154 may be formed on the gate insulation layer 152 on the second region R2.

In some implementations, the plurality of upper electrodes 166 may be arranged on the insulating layer 164, and may be arranged to be offset from the plurality of lower electrodes 162 in the first horizontal direction X. The plurality of upper electrodes 166 may be spaced apart from each other in the first horizontal direction X by a second separation distance sd2 that is substantially the same as the first separation distance sd1. In some other implementations, the second separation distance sd2 may be greater than the first separation distance sd1, and in some other implementations, the second separation distance sd2 may be less than the first separation distance sd1.

In some implementations, a sidewall of one upper electrode may be arranged to be spaced apart by a third separation distance sd3 from a sidewall of one lower electrode. The third separation distance sd3 may be less than the first separation distance sd1 or the second separation distance sd2. Even when a minimum separation distance allowed by the design rule is the first separation distance sd1 or the second separation distance sd2, a first electrode stack including one lower electrode and one upper electrode may be spaced apart from a second electrode stack including another lower electrode and another upper electrode by a third separation distance sd3 less than the first separation distance sd1 or the second separation distance sd2.

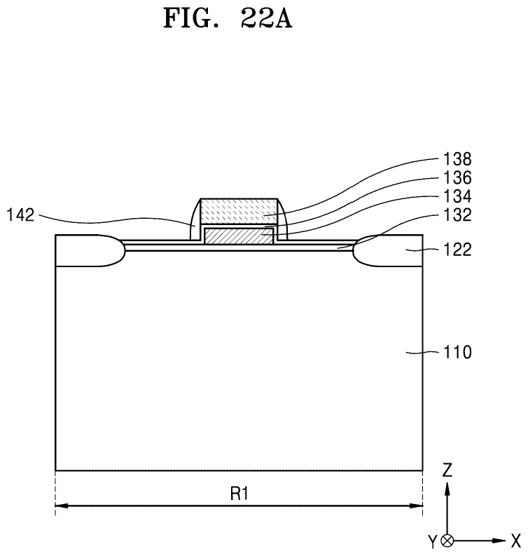

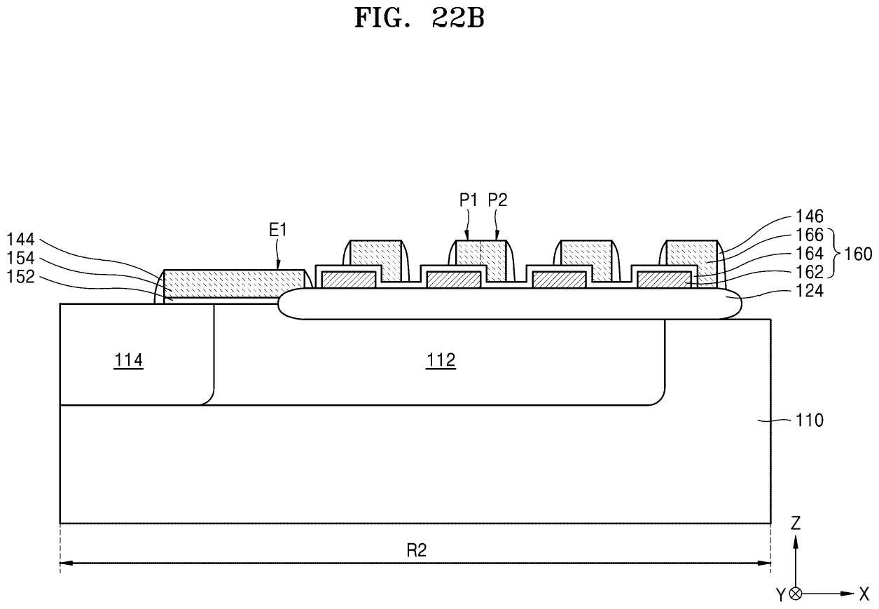

Referring to FIGS. 22A and 22B, a first spacer 142 may be formed on a sidewall of the control gate electrode 138 on the first region R1, a second spacer 144 may be formed on a sidewall of the gate electrode 154 on the second region R2, and a third spacer 146 may be formed on a sidewall of each of the plurality of upper electrodes 166.

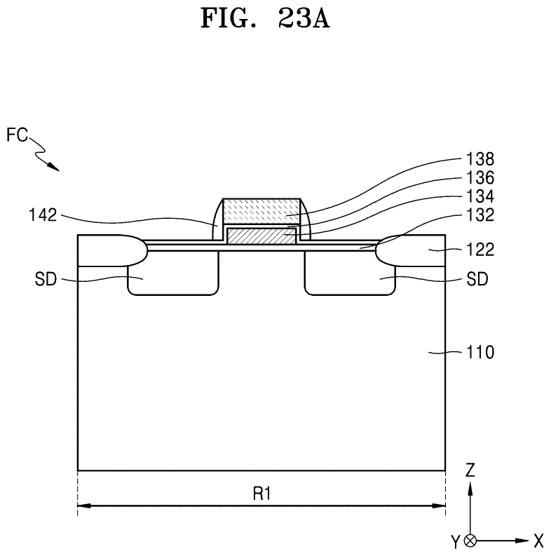

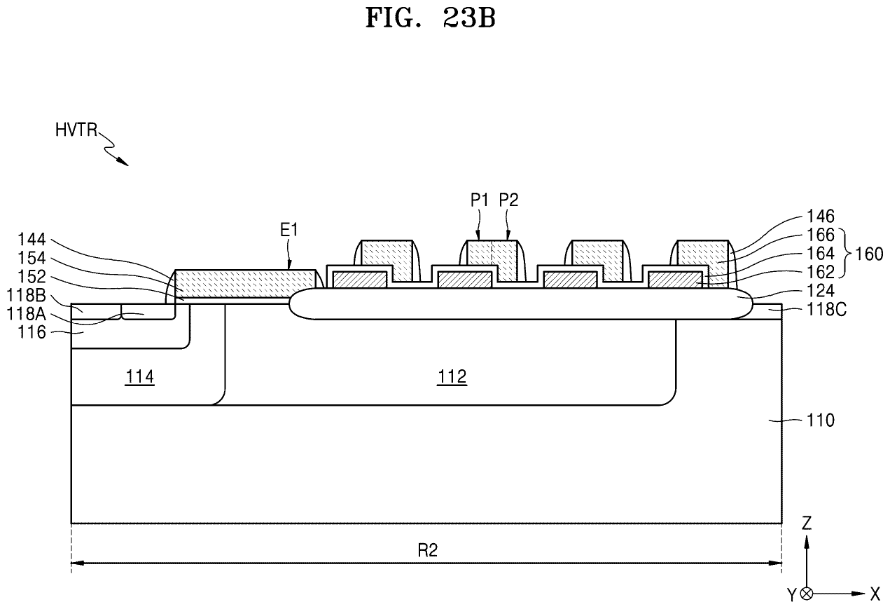

Referring to FIGS. 23A and 23B, a body region 116 may be formed by implanting impurity ions into the second region R2 of the substrate 110. In some implementations, the body region 116 may be formed adjacent to one side of the gate electrode 154.

Then, a source region 118A, a body contact region 118B, and a drain region 118C may be formed by implanting impurity ions into the second region R2 of the substrate 110. In some implementations, the source region 118A and the drain region 118C may be formed by injecting first conductivity type impurities (e.g., n-type impurities) into the substrate 110, and the body contact region 118B may be formed by injecting second conductivity type impurities (e.g., p-type impurities) into the substrate 110.

Thereafter, impurity ions may be implanted into the first region R1 of the substrate 110 to form impurity regions SD.

The semiconductor device 100 may be formed by performing the above-described processes.

In the method of manufacturing the semiconductor device 100 according to implementations, the flash memory cell FC and the MOS transistor HVTR may be formed using same process. For example, the floating gate electrode 134 of the flash memory cell FC and the lower electrodes 162 of the MOS transistor HVTR may be formed at same manufacturing process, and the control gate electrode 138 of the flash memory cell FC and the gate electrode 154 and the upper electrodes 166 of the MOS transistor HVTR may be formed at same manufacturing process. Accordingly, the number of manufacturing processes of the semiconductor device 100 may be reduced.

In addition, the floating electrode structure 160 includes a plurality of lower electrodes 162, and a plurality of upper electrodes 166 that are respectively offset from the plurality of lower electrodes 162. Accordingly, the gaps between the plurality of electrodes may be minimized without being limited to the minimum design rule. An electric field concentrated on the edge of the gate electrode 154 may be effectively dispersed by a coupling effect between the lower electrodes 162 and the upper electrodes 166, and the semiconductor device 100 may have a high breakdown voltage.

According to the present disclosure, a floating electrode structure is arranged on a field oxide layer, and the floating electrode structure includes a plurality of lower electrodes and a plurality of upper electrodes offset the plurality of lower electrodes. Accordingly, the gaps between the plurality of electrodes may be minimized without being limited to the minimum design rule, and an electric field concentrated on the gate electrode edge may be effectively dispersed by the coupling effect between the upper electrodes and the lower electrodes, and the semiconductor device may have a high breakdown voltage. In addition, the floating electrode structure may be simultaneously formed in a process of manufacturing the floating gate electrode and the control gate electrode of the embedded flash device. Accordingly, the number of process steps for manufacturing the semiconductor device may be reduced.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A semiconductor device comprising:
a substrate;
a drift region and a body region in an upper portion of the substrate, wherein the drift region has a first conductivity type and the body region has a second conductivity type;
a field oxide layer on the drift region of the substrate;
a gate electrode on the substrate and vertically overlapping a portion of the drift region and a portion of the body region, the gate electrode including a first extension portion on the field oxide layer;
a source region on a first side of the gate electrode in the body region of the substrate;
a drain region on a first side of the field oxide layer within the drift region of the substrate; and
a floating electrode structure on the field oxide layer between the gate electrode and the drain region, the floating electrode structure including
a plurality of lower electrodes spaced apart from each other in a first horizontal direction on a top surface of the field oxide layer,
an insulating layer covering top surfaces of the plurality of lower electrodes, and
a plurality of upper electrodes on the insulating layer and each vertically overlapping a portion of a respective one of the plurality of lower electrodes.

2. The semiconductor device of claim 1, wherein
each of the plurality of lower electrodes has a rectangular vertical cross-section, and
each of the plurality of upper electrodes has an inverted L-shaped vertical cross-section.

3. The semiconductor device of claim 1, wherein each of the plurality of upper electrodes comprises:
a first portion on a top surface of a respective one of the plurality of lower electrodes; and
a second portion on a sidewall of a respective one of the plurality of lower electrodes and integrally connected to the first portion.

4. The semiconductor device of claim 3, wherein
a top surface of the first portion is coplanar with a top surface of the second portion, and
a bottom surface of the first portion is at a higher vertical level than a bottom surface of the second portion.

5. The semiconductor device of claim 3, wherein
the plurality of lower electrodes comprise a first lower electrode and a second lower electrode adjacent to the first lower electrode, and
the plurality of upper electrodes comprise a first upper electrode on the first lower electrode, and a second upper electrode on the second lower electrode, and
wherein the first lower electrode is spaced apart from the second lower electrode by a first separation distance in the first horizontal direction,
the first upper electrode is spaced apart from the second upper electrode by a second separation distance in the first horizontal direction, and
the second separation distance is equal to the first separation distance.

6. The semiconductor device of claim 3, wherein
the plurality of lower electrodes comprise a first lower electrode and a second lower electrode adjacent to the first lower electrode, and
the plurality of upper electrodes comprise a first upper electrode on the first lower electrode, and a second upper electrode on the second lower electrode, and
wherein the first lower electrode is spaced apart from the second lower electrode by a first separation distance in the first horizontal direction,
the first upper electrode is spaced apart from the second upper electrode by a second separation distance in the first horizontal direction,
the second upper electrode is spaced apart from the first lower electrode by a third separation distance in the first horizontal direction, and
the third separation distance is less than the first separation distance or the second separation distance.

7. The semiconductor device of claim 3, wherein
a bottom surface of each of the plurality of lower electrodes is in contact with the top surface of the field oxide layer,
a first portion of the insulating layer is between a bottom surface of the first portion of each of the plurality of upper electrodes and the top surface of each of the plurality of lower electrodes, and
a second portion of the insulating layer is between a bottom surface of the second portion of each of the plurality of upper electrodes and the top surface of the field oxide layer.

8. The semiconductor device of claim 1, wherein the field oxide layer comprises local oxidation of silicon (LOCOS) oxide.

9. The semiconductor device of claim 1, wherein
the source region has the first conductivity type, and
the drain region has the first conductivity type.

10. The semiconductor device of claim 1, wherein top surfaces of the plurality of upper electrodes are at a same vertical level.

11. The semiconductor device of claim 1, wherein the floating electrode structure is configured to float based on a gate voltage being applied to the gate electrode.

12. The semiconductor device of claim 1, wherein the gate electrode is spaced apart from the floating electrode structure in the first horizontal direction.

13. The semiconductor device of claim 1, wherein the floating electrode structure comprises:
an edge electrode between the plurality of lower electrodes and the gate electrode, the edge electrode being adjacent to the first extension portion of the gate electrode, and
the gate electrode comprises a second extension portion on a top surface of the edge electrode and at a vertical level higher than the first extension portion.

14. The semiconductor device of claim 13, wherein a top surface of the second extension portion of the gate electrode is at a same vertical level as top surfaces of the plurality of upper electrodes.

15. A semiconductor device comprising:
a substrate;
a drift region and a body region in an upper portion of the substrate, wherein the drift region has a first conductivity type, and the body region has a second conductivity type;
a field oxide layer on the drift region of the substrate;
a gate electrode on the substrate and vertically overlapping a portion of the drift region and a portion of the body region;
a source region on a first side of the gate electrode in the body region of the substrate;
a drain region on a first side of the field oxide layer within the drift region of the substrate; and
a floating electrode structure on the field oxide layer and between the gate electrode and the drain region, the floating electrode structure including
a plurality of lower electrodes spaced apart from each other by a first separation distance in a first horizontal direction on a top surface of the field oxide layer,
a plurality of upper electrodes each offset from a respective one of the plurality of lower electrodes in the first horizontal direction, the plurality of upper electrodes spaced apart from each other by a second separation distance equal to the first separation distance in the first horizontal direction, and
an insulating layer between the plurality of lower electrodes and the plurality of upper electrodes.

16. The semiconductor device of claim 15, wherein each of the plurality of upper electrodes comprises:
a first portion on a top surface of a respective one of the plurality of lower electrodes; and
a second portion on a sidewall of a respective one of the plurality of lower electrodes and integrally connected to the first portion.

17. The semiconductor device of claim 16, wherein the first portion of each of the plurality of upper electrodes vertically overlaps a respective one of the plurality of lower electrodes.

18. The semiconductor device of claim 15, wherein
each of the plurality of lower electrodes has a rectangular vertical cross-section, and
each of the plurality of upper electrodes has an inverted L-shaped vertical cross-section.

19. A semiconductor device comprising:
a flash memory cell on a first region of a substrate; and
a metal oxide semiconductor (MOS) transistor on a second region of the substrate,
wherein the MOS transistor comprises
a drift region and a body region in an upper portion of the substrate, wherein the drift region has a first conductivity type, and the body region has a second conductivity type,
a field oxide layer on the drift region of the substrate,
a gate electrode on the substrate and vertically overlapping a portion of the drift region and a portion of the body region,
a source region on a first side of the gate electrode in the body region of the substrate,
a drain region on a first side of the field oxide layer within the drift region of the substrate, and
a floating electrode structure on the field oxide layer and between the gate electrode and the drain region, the floating electrode structure including:
a plurality of lower electrodes spaced apart on a top surface of the field oxide layer;
an insulating layer covering top surfaces of the plurality of lower electrodes; and
a plurality of upper electrodes on the insulating layer and each vertically overlapping a portion of a respective one of the plurality of lower electrodes.

20. The semiconductor device of claim 19, wherein
the plurality of lower electrodes comprise a first lower electrode and a second lower electrode adjacent to the first lower electrode, and
the plurality of upper electrodes comprise a first upper electrode on the first lower electrode, and a second upper electrode on the second lower electrode,
wherein the first lower electrode is spaced apart from the second lower electrode by a first separation distance in a first horizontal direction,
the first upper electrode is spaced apart from the second upper electrode by a second separation distance in the first horizontal direction, the second separation distance is equal to the first separation distance,
the second upper electrode is spaced apart from the first upper electrode by a third separation distance in the first horizontal direction, and
the third separation distance is less than the first separation distance.
